(19) United States
(12) Patent Application Publication
(10) Pub. No.: US 2016/0109519 A1
(43) Pub. Date: Apr. 21, 2016

(54) SYSTEM AND METHOD FOR ELIMINATING INDETERMINISM IN INTEGRATED CIRCUIT TESTING

(71) Applicants: Vishal Vadhavania, Noida (IN); Akhil Jain, Greater Noida (IN); Sachin Jain, New Delhi (IN); Arvind Garg, Chandigarh (IN)

(72) Inventors: Vishal Vadhavania, Noida (IN); Akhil Jain, Greater Noida (IN); Sachin Jain, New Delhi (IN); Arvind Garg, Chandigarh (IN)

(21) Appl. No.: 14/516,557

(22) Filed: Oct. 16, 2014

(51) Int. Cl. G01R 31/317; G01R 31/3177

(52) U.S. Cl. CPC G01R 31/31727; G01R 31/3177

(57) ABSTRACT

Indeterministic launch of test transactions in a system-on-chip device having asynchronous paths may be avoided by gating test mode bus transactions at the functional (IP) module interface. The gated bus transactions are released using an external trigger in order to control loss of cycle accuracy caused by on-board synchronizers during functional testing. Conventional interfaces can be driven from automatic test equipment and controlled in order to account for PVT variations and achieve deterministic and stable behavior of the device while being tested.

### BACKGROUND OF THE INVENTION

The present invention relates generally to integrated circuits and methods of testing integrated circuits and, more particularly, to testing integrated circuits that include asynchronous paths.

Integrated circuits undergo testing before being deemed fit for operation. One such type of testing involves using Automatic Test Equipment (ATE) to check the integrated circuit's input/output (I/O) interface signal timing with respect to a reference signal. Typically, test patterns are used to configure the functional circuits of the integrated circuit to output actual data at the I/O interface in defined cycles, and the ATE is configured to expect the same data on the I/O interfaces in same cycles. If the output data captured by the ATE does not match the expected test data, the integrated circuit is considered faulty. Some integrated circuits, for example certain core-based system on chip (SOC) devices, are designed to contain many asynchronous paths in order to achieve high speed timings at low power. Consequently, due to the asynchronous nature of the data transfers, the times at which outputs appear at the I/O interfaces are indeterminate. Many factors and process variations are known to introduce this variance, such as process, temperature, and voltage (PVT) variation, for example. Changes in these factors may impact the data transfer timings and lead to cycle-shifted outputs at the I/O interfaces. The ATE would consider such cycle-shifted outputs as erroneous and thus the device would fail the test and result in yield loss. Hence, this presents a challenge when testing an SOC using cycle-based testers such as are found in typical automated test equipment (ATE). Even though the functionality of an interface may be met by the design under testing, the cycle accuracy is compromised. So it can be extremely difficult and sometimes impossible to stabilize tester patterns across different PVT conditions.

Thus it would be advantageous to eliminate indeterminate behavior in semiconductor devices during testing.

### BRIEF DESCRIPTION OF THE DRAWINGS

The invention, together with objects and advantages thereof, may best be understood by reference to the following description of preferred embodiments together with the accompanying drawings in which:

FIG. 1 is a schematic block diagram of a conventional System on Chip device;

FIG. 2 is a schematic block diagram of a system on chip device including test circuitry in accordance with an embodiment of the present invention; and

FIG. 3 is a timing diagram illustrating operation of the system on chip device of FIG. 2.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a circuit for enabling deterministic launch of a test transaction in an integrated circuit that includes a functional module. The circuit comprises a gate module for receiving a trigger signal and a test transaction, and is arranged to gate or enable the test transaction, for application to an interface of the functional module, dependent on a logical state of the trigger signal.

In another embodiment, the present invention provides a method for enabling deterministic launch of a test transaction in an integrated circuit that includes a functional module. The method comprises: generating a test transaction and applying the test transaction to the integrated circuit via a test port; generating a trigger signal; and inhibiting or enabling the test transaction from reaching an interface of the functional module, dependent on a logical state of the trigger signal.

In one example, test mode bus transactions are gated and on-board synchronizers are by-passed at the functional (IP) module interface. The gated bus transactions are released using an external trigger in order to control loss of cycle accuracy caused by on-board synchronizers during functional testing. The invention may, advantageously, make use of the conventional General Purpose Input-Output (GPIO) interfaces provided on the semiconductor device which are driven from external ATE during a test procedure. The GPIOs can be controlled in order to account for PVT variations and achieve deterministic and stable behavior of the device while being tested.

Advantageously, no modifications to any of the functional (IP) modules comprising the device need to be made. The method in accordance with the invention may be used in any SOC testing procedure independent of the type of IP modules included in the SOC design.

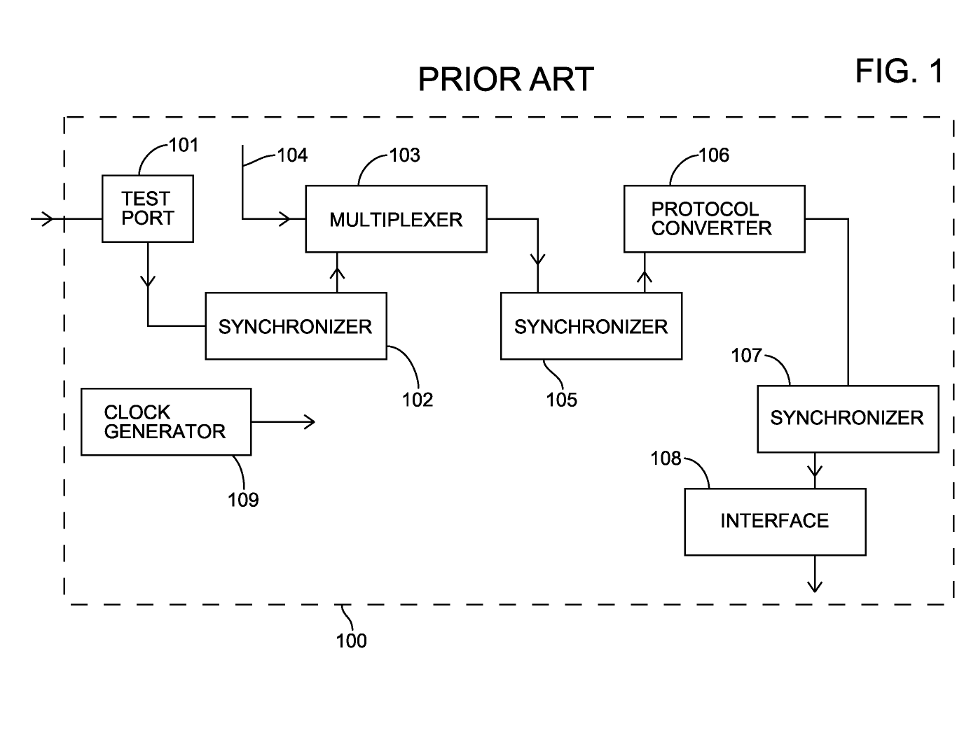

Referring now to FIG. 1, a schematic block diagram of a typical core-based, system on chip device (SOC) 100 is shown. The SOC 100 includes a test port 101 that is operably coupled through a first synchronizer 102 to a multiplexer 103. The test port 101 is provided at the SOC periphery in order to program the device's internal functional modules while testing the SOC 100. In a test mode, the test port 101 receives signals from an automatic test equipment (not shown). The multiplexer 103 behaves like a crossbar switch and is used to route requests of different masters (not shown) received on an input line 104 to different slaves (not shown). It is also used to route test transactions received from the test port 101. In this example, the masters and slaves work on the “so-called Advanced eXtensible Interface” (AXI) bus protocol. The multiplexer 103 is operably coupled via a second synchroniser 105 to a protocol converter 106, which in this example is an AHB (Advanced High performance Bus) to IP bus protocol. The so-called IP Interface Standard defines a set of common architecture and input/output (I/O) signal standards for the design and verification of SOC components. These components are sometimes referred to as “IP” (intellectual property) components or functional modules. An IP bus is an interface that can be used to access architecture registers of a module. See for example, Freescale Semiconductor Technical Note IPMXDSRSIPI00001 “IP Interface, Semiconductor Re-use Standard” SRS V3.2 Feb. 2005. The protocol converter 106 is operably coupled via a third synchroniser 107 to an interface 108. The interface 108 is a bus interface to a functional module (not shown). A clock generator 109 provides clocking signals for the SOC 100. The SOC typically also comprises other modules such aa a core, functional modules such as UART (universal asynchronous receiver/transmitter) and SPI (serial peripheral interface), for example, and input/output (IO) interfaces.

During a test mode of the device, test mode transactions are launched from the device periphery through the test port 101. These transactions are converted by the test port 101 to internal bus protocol signals (AXI in this example), which are then routed to the multiplexer 102. Typically, these transactions pass through various protocol converters for example magenta, AXI, AHB and IP bus before they reach a destination register interface of a functional module. Through the interface 108 associated with a particular functional module, these transactions write into a register inside the functional module resulting in launch of the transactions on the device interface. The synchronizers 102, 105, 107 present between the various protocol converters represent the asynchronous interfaces which are typically present in the SOC device 100. Owing to the presence of the asynchronous interfaces, the time of launch of test mode transactions relative to receipt of a transaction at the test port 101 can vary depending on the prevailing PVT conditions. Current ATE testing requirements stipulate that this variation should be within one ATE clock cycle. The known arrangement of FIG. 1 cannot achieve this.

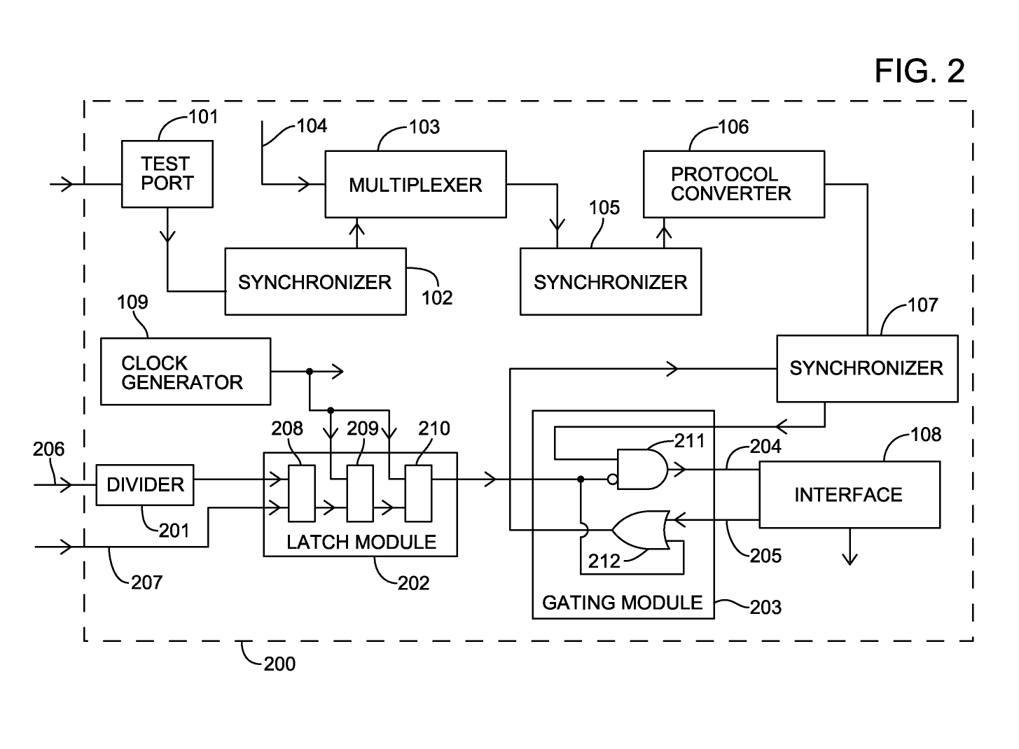

An integrated circuit such as a system on chip (SOC) device that includes a circuit for enabling the device to achieve determinism in launching of a test signal, as required by the ATE testing procedure, will now be described with reference to FIG. 2. Modules which are common to both FIG. 1 and FIG. 2 have been given the same reference numerals. An SOC 200 includes circuitry 201, 202, 203 for permitting a deterministic test transaction signal to be presented at the interface 108. The SOC typically also comprises other modules such as a core, functional modules such as UART (universal asynchronous receiver/transmitter) and SPI (serial peripheral interface), for example, and input/output (IO) interfaces. In common with the SOC of FIG. 1, the SOC 200 includes a test port 101 that is operably coupled through a first synchronizer 102 to a multiplexer 103. The test port 101 receives test transaction signals from an automatic test equipment (ATE) (not shown). The multiplexer 103 routes the test transactions received from the test port 101 to other parts of the SOC. The multiplexer 103 is operably coupled via a second synchroniser 105 to a protocol converter 106 which in this example is an AHB to IP bus protocol converter. The protocol converter 106 is operably coupled via a third synchroniser 107 to the gating module 203. An output of the gating module is fed, on line 204, to the interface 108. The gating module receives a signal on line 205 from the interface 108. The interface 108 is a bus interface to a functional module (not shown). A clock generator 109 provides clocking signals for the SOC 200 and also for a programmable clock divider module 201. The clock divider 201 module also receives, on line 206, a ‘divider enable’ signal which is provided by ATE (not shown). In one example, a divider value is held in a register located in the clock divider module's register map. Alternatively, a general purpose register can be used. In this example, the divider value is four. That is, the clock divider module produces a clock signal whose frequency is one quarter of the frequency of that produced by the clock generator 109. This divided clock signal is fed to a first input of a latch module 202. In this example, a typical clock frequency generated by the clock generator module 109 is 156 MHz and that produced by the clock divider module 201 is 39 MHz. However, other frequencies are possible. The latch module 202 receives a second input on line 207. This second input is an external trigger generated by ATE (not shown).

The latch module 202 comprises three flip-flops 208, 209, 210 arranged in series. A first flop-flop 208 receives the divided clock output from the clock divider module 201 at its clock input and receives the external trigger on line 207 from the ATE at its signal input. The second flip flop 209 receives the clock signal generated by the clock generator 109 at its clock input and an output from the first flip-flop 208 at its signal input. The third flip flop 210 receives the clock signal generated by the clock generator 109 at its clock input and an output from the second flip-flop 209 at its signal input. An output of the third flip-flop 210 is operably coupled to the gating module 203.

The gating module 203 in this embodiment is configured to support IP bus protocol and comprises an AND gate 212 and an OR gate 211. The AND gate receives the output from the protocol converter 106 via the third synchronizer 107 at a first input and an inverted version of the output from the third flip-flop of the latch module 202 at a second input. The output of the AND gate 211 is fed to the interface 108. The OR gate receives an output from the interface 108 and the output from the third flip-flop 210. An output of the OR gate is fed to the protocol converter 106 via the third synchronizer 107. In another embodiment, the gating module 203 is configured to support the AXI protocol by replacing the OR gate 212 with a second AND gate (not shown). In this alternative embodiment, the signal received from the output of the third flip-flop 210 is inverted before being applied to the second AND gate.

The purpose of the gating module 203 is to gate “IPS” module enable signals (e.g., read/write transactions) under the control of the ATE and more specifically, to gate and enable the handshaking signals of the interface 108 that are used in a read/write operation on registers of a functional module of the SOC 200. In the embodiment of FIG. 2, the AND gate 211 in the gating module 203 gates the IPS transactions (i.e., the IPS module-enable signals) coming from the protocol converter 106 by keeping its output to the interface 108 on line 204 at a logical ‘low’ until a gating trigger signal received from the output of the latch module 202 is de-asserted. Similarly, the OR gate 212 in the gating module 203 gates the IPS XFR (transfer) Wait signal received from the interface 108 on line 205 by keeping its output to the protocol converter 106 at a logical ‘high’ until the gating trigger signal is de-asserted. (In this example, IPS XFR Wait signal is used to insert wait states for a read/write transaction).

The purpose of the latch module 202 is to generate the gating signal by propagating the received external trigger from the ATE on line 207 under the control of clock signals from the clock divider module 201. In order to gate a transaction appearing at the gating module 203, the external trigger supplied by the ATE on line 207 is held at a logical ‘high.’ To launch the transaction, the external trigger is de-asserted and is latched by the first flip-flop 208 on the slower clock signal from the clock divider module 201. It then passes through the second and third flip-flops 209, 210 on the faster clock signal supplied by the clock generator 109. The two additional flip-flops ease timing requirements and eliminate meta-stability on the propagated signal.

The output of the clock divider module 201 serves to capture the external trigger provided by the ATE. Providing a lower frequency for this purpose than would be provided by the clock generator 109 has the advantage of easing the timing requirements on the signal path between an SOC pad receiving the external trigger and the first flip-flop 208. The clock divider module 201 is controlled by the divider enable signal received on line 206 from the ATE and generated by the ATE at some specific time during a test cycle.

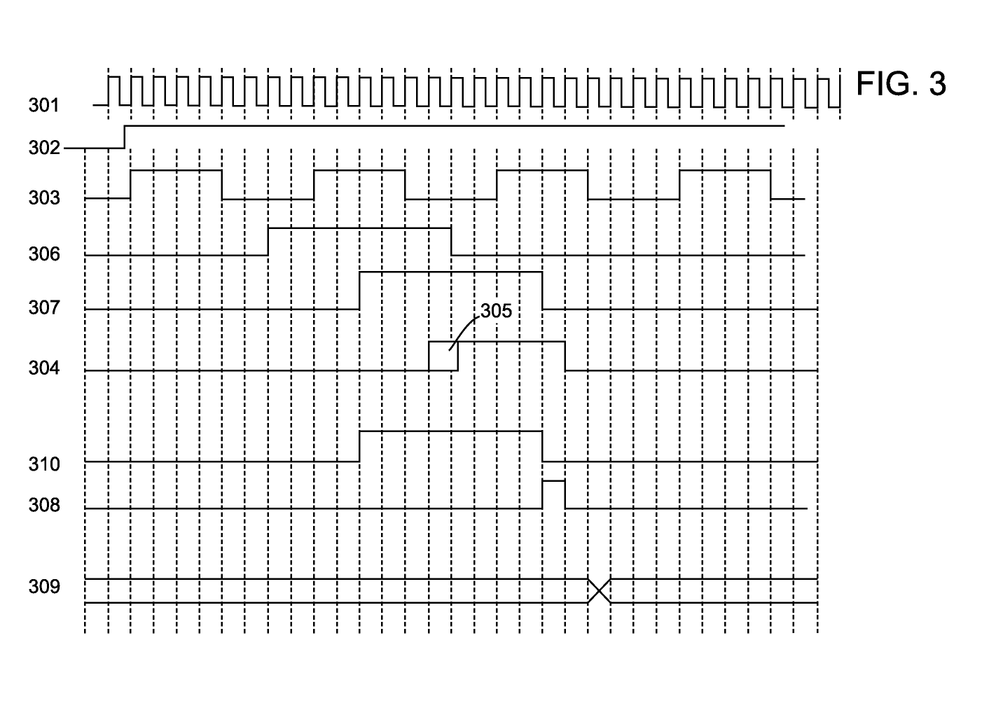

Referring now to FIG. 3, a timing diagram shows a trace 301 that represents a clock signal that is generated by the clock generator 109 and applied to the second and third flip-flops 209, 210 and to the clock divider module 201. Trace 302 represents an enable signal which is generated by an external ATE at some specific time during the ATE operating cycle and applied to the clock divider module 201 on line 206. In this example, when the enable signal goes high, the divider commences to generate the lower clock frequency which is used by the first flip-flop 208 and represented by trace 303. Trace 304 represents an IPS module enable signal appearing at the output of the third synchronizer 107 (and so at one of the inputs of the gating module 203) as a result of a test transaction generated by an external ATE being applied to the SOC at the test port 101. The time of arrival at the gating module of this signal after being applied to the test port is indeterminate (represented by reference numeral 305) owing to the presence of asynchronous paths in the SOC. Trace 306 represents an external trigger signal generated by an external ATE and applied to the latch module on line 207. Trace 307 represents the external trigger signal (306) after it has propagated through the latch module 202 and subsequently arrives at an input of the gating module 203 as a “gating trigger signal.” As the action of the clock divider module 201 (once enabled) controls the propagation of the external trigger signal through to the gating module 203, the gating trigger signal 307 will always bear the same temporal relationship to the ATE operating cycle. While the gating trigger signal 307 is high (asserted), the IPS module enable signal will be gated and so held off (by the AND gate 211) from reaching the interface 108. When the gating trigger signal goes low (de-asserted), then the AND gate will allow the IPS module enable signal 304 to reach the interface 108. This is represented by trace 308. As a result, signals at the SOC interfaces will toggle deterministically (as represented in trace 309). Trace 310 represents the output of the OR gate 212.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice-versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals. Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one or ‘high’, the logically false state is a logic level zero or ‘low’ and if the logically true state is a logic level zero or ‘low’, the logically false state is a logic level one or ‘high’.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Further, the entire functionality of the modules shown in FIG. 2 may be implemented in an integrated circuit. Such an integrated circuit may be a package containing one or more dies. Alternatively, the examples may be implemented as any number of separate integrated circuits or separate devices interconnected with each other in a suitable manner. An integrated circuit device may comprise one or more dies in a single package with electronic components provided on the dies that form the modules and which are connectable to other components outside the package through suitable connections such as pins of the package and bond wires between the pins and the dies.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A circuit for enabling deterministic launch of a test transaction in an integrated circuit that includes a functional module, the circuit comprising:
a gate module for receiving a trigger signal and a test transaction, wherein the gate module is arranged to gate or enable the test transaction for application to an interface of the functional module, dependent on a logical state of the trigger signal.

2. The circuit of claim 1, further comprising:
a latch module operably coupled to the gate module; and
a clock module operably coupled to the latch module,
wherein the latch module applies the trigger signal to the gate module under the control of a clock signal generated by the clock module.

3. The circuit of claim 2, wherein the latch module comprises three flip-flops connected in series, and the first flip-flop receives a clock input of frequency F1 and the second and third flip-flops receive clock inputs of frequency F2, wherein F2 is greater than F1.

4. The circuit of claim 2, wherein the clock module is arranged to generate the clock signal on receipt of a clock enable signal.

5. The circuit of claim 1, wherein the gate module is arranged to gate or enable handshake signals applied to and received from the interface of the functional module.

6. The circuit of claim 5, wherein the gate module includes an AND gate for gating or enabling the test transaction depending on a logical state of the trigger signal, and an OR gate for gating or enabling a wait signal received from the interface of the functional module depending on a logical state of the trigger signal.

7. The circuit of claim 5, wherein the gate module includes a first AND gate for gating or enabling the test transaction depending on a logical state of the trigger signal, and a second AND gate for gating or enabling a wait signal received from the interface of the functional module depending on a logical state of the trigger signal.

8. A method for enabling deterministic launch of a test transaction in an integrated circuit that includes a functional module, the method comprising:
generating a test transaction and applying said test transaction to the integrated circuit via a test port;
generating a trigger signal; and
inhibiting or enabling the test transaction from reaching an interface of the functional module, dependent on a logical state of the trigger signal.

9. The method of claim 8, comprising:
generating an enable signal for enabling a clock generator and controlling generation of the trigger signal with a clock signal generated by the clock generator when enabled by said enable signal.

10. An integrated circuit, comprising:
a functional module;
a clock generator for providing a first clock signal;
a clock module, operably coupled to the clock generator, for dividing the first clock signal to produce a second clock signal on receipt of an externally-generated enable signal;
a latch module, operably coupled to the clock generator and to the clock module, for receiving an externally-generated trigger signal at an input thereof and for propagating the trigger signal to an output thereof under the control of the first and second clock signals; and
a gate module, operably coupled to the latch module, for receiving the propagated trigger signal from the output of the latch module and an externally-generated test transaction, and for gating or enabling the test transaction for application to an interface of the functional module dependent on a logical state of the propagated trigger signal.
